(19) United States
(12) Patent Application Publication
(10) Pub. No.: US 2025/0316486 A1
(43) Pub. Date: Oct. 9, 2025

(54) Method of Uniform NiSi Deposition

(71) Applicant: Wolfspeed, Inc., Durham, NC (US)

(72) Inventors: Afshin Dadvand, Durham, NC (US); Pavel Nikolayevich Moroz, Durham, NC (US)

(21) Appl. No.: 18/627,134

(22) Filed: Apr. 4, 2024

(51) Int. Cl. H01L 21/285; H01L 21/04; H01L 21/28; H01L 21/768

(52) U.S. Cl. CPC H01L 21/28518; H01L 21/0485; H01L 21/28052; H01L 21/76895

(57) ABSTRACT

Semiconductor device packages and methods for manufacturing the same are provided. In one example, a semiconductor structure may be provided on a substrate, and a metastable reactive layer may be provided on the semiconductor structure. Energy may be applied to the metastable reactive layer to form a silicide layer on the semiconductor structure, and, in some examples, a metallization structure may be provided on the silicide layer.

### FIELD

The present disclosure relates generally to semiconductor devices.

### BACKGROUND

Power semiconductor devices are used to carry large currents and support high voltages. A wide variety of power semiconductor devices are known in the art including, for example, transistors, diodes, thyristors, power modules, discrete power semiconductor packages, and other devices. For instance, example semiconductor devices may be transistor devices such as Metal Oxide Semiconductor Field Effect Transistors (“MOSFET”), bipolar junction transistors (“BJTs”), Insulated Gate Bipolar Transistors (“IGBT”), Gate Turn-Off Transistors (“GTO”), junction field effect transistors (“JFET”), high electron mobility transistors (“HEMT”) and other devices. Example semiconductor devices may be diodes, such as Schottky diodes or other devices.

Power semiconductor devices may be packaged into various semiconductor device packages, such as discrete semiconductor device packages and power modules. Power modules may include one or more power devices and other circuit components and can be used, for instance, to dynamically switch large amounts of power through various components, such as motors, inverters, generators, and the like.

Semiconductor devices may be fabricated from wide bandgap semiconductor materials, such as silicon carbide and/or Group III nitride-based semiconductor materials. The fabrication process for power semiconductor devices may require processing of wide bandgap semiconductor wafers, such as silicon carbide semiconductor wafers.

### SUMMARY

Aspects and advantages of embodiments of the present disclosure will be set forth in part in the following description, or can be learned from the description, or can be learned through practice of the embodiments.

One example aspect of the present disclosure is directed to a method. The method includes providing a semiconductor structure on a substrate. The method includes providing a metastable reactive layer on the semiconductor structure. The method includes applying energy to the metastable reactive layer to form a silicide layer on the semiconductor structure.

Another example aspect of the present disclosure is directed to a method. The method includes providing a semiconductor structure on a substrate. The method includes providing a thermite structure on the semiconductor structure. The method includes providing an ignition-deposited silicide layer on the semiconductor structure. The method includes providing a metallization structure on the ignition-deposited silicide layer.

Another example aspect of the present disclosure is directed to a semiconductor device package. The semiconductor device package includes a submount, a semiconductor structure having a metastable-reactive-layer-deposited silicide, and a metallization layer on the metastable-reactive-layer-deposited silicide. The metallization layer is between the submount and the semiconductor structure.

Another example aspect of the present disclosure is directed to a semiconductor die. The semiconductor die includes a metastable-reactive-layer-deposited silicide and a metallization layer on the metastable-reactive-layer-deposited silicide.

Another example aspect of the present disclosure is directed to a semiconductor wafer. The semiconductor wafer includes a semiconductor substrate, a metastable-reactive-layer-deposited silicide on the semiconductor substrate, and a metallization layer on the metastable-reactive-layer-deposited silicide.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures, in which:

FIG. 1A depicts a top view of an example semiconductor wafer according to example embodiments of the present disclosure;

FIG. 1B depicts a bottom view of the example semiconductor wafer of FIG. 1A according to example embodiments of the present disclosure;

FIG. 2 depicts an overview of an example method according to example embodiments of the present disclosure;

FIG. 3 depicts an overview of an example method according to example embodiments of the present disclosure;

FIG. 4 depicts an overview of the example method of FIG. 3 according to example embodiments of the present disclosure;

FIG. 5 depicts an overview of the example method of FIG. 3 according to example embodiments of the present disclosure;

FIG. 6 depicts an overview of an example method according to example embodiments of the present disclosure;

FIG. 7 depicts a flow chart diagram of an example method according to example embodiments of the present disclosure;

FIG. 8 depicts a flow chart diagram of an example method according to example embodiments of the present disclosure;

FIG. 9 depicts an example semiconductor package of a semiconductor device according to example embodiments of the present disclosure; and

FIG. 10 depicts an example semiconductor package of a semiconductor device according to example embodiments of the present disclosure.

Repeat use of reference characters in the present specification and drawings is intended to represent the same and/or analogous features or elements of the present invention.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations may be made to the embodiments without departing from the scope or spirit of the present disclosure. For instance, features illustrated or described as part of one embodiment may be used with another embodiment to yield a still further embodiment. Thus, it is intended that aspects of the present disclosure cover such modifications and variations.

Semiconductor device packages (e.g., discrete semiconductor device packages and power modules) have been developed that include a semiconductor die, such as a metal-oxide-semiconductor field-effect transistor (MOSFET), a Schottky diode, and/or a high electron mobility transistor (HEMT) device. Semiconductor device packages with MOSFETs may be employed in a variety of applications to enable higher switching frequencies along with reduced associated losses, higher blocking voltages, and improved avalanche capabilities. Example applications may include high performance industrial power supplies, server/telecom power, electric vehicle charging systems, energy storage systems, uninterruptible power supplies, high-voltage DC/DC converters, electric vehicles, and battery management systems. Semiconductor device packages with Schottky diodes and/or HEMT devices may be employed in many of the same high-performance power applications described above for MOSFETs, sometimes in systems that also include discrete power packages of MOSFETs.

Example aspects of the present disclosure are directed to semiconductor devices and semiconductor device packages for use in semiconductor applications and other electronic applications. It should be understood that the terms “semiconductor device package” and “semiconductor package” may be used interchangeably. In some examples, semiconductor device packages may include one or more semiconductor structures, such as semiconductor die, semiconductor device(s), and the like. In some examples, semiconductor structures of the present disclosure may include a wide bandgap semiconductor material, such as silicon carbide (SiC) semiconductor materials and/or Group III nitride-based (e.g., gallium nitride (GaN) semiconductor materials. For instance, in some examples, an example semiconductor device package may include a semiconductor structure having, e.g., wide bandgap semiconductor device(s), silicon carbide-based semiconductor device(s) (e.g., MOSFETs, Schottky diodes), Group III nitride-based semiconductor device(s) (e.g., HEMT devices), and the like.

As used herein, a “wide bandgap semiconductor material” refers to a semiconductor material having a band gap greater than about 1.40 eV. Aspects of the present disclosure are discussed herein with reference to silicon carbide-based semiconductor structures/layers as wide bandgap semiconductor structures/layers for purposes of illustration and discussion. Those having ordinary skill in the art, using the disclosures provided herein, will understand that any suitable semiconductor material, such as other wide bandgap semiconductor materials, may be used without deviating from the scope of the present disclosure. By way of non-limiting example, example wide bandgap semiconductor materials include silicon carbide and/or Group III-nitrides.

Semiconductor devices may be fabricated by performing fabrication processes on a semiconductor wafer. A semiconductor wafer is a thin, disc-shaped sheet of semiconductor material (e.g., silicon (Si), SiC, GaN, etc.) that may serve as the foundation for manufacturing semiconductor devices, such as integrated circuits (ICs) and/or other electronic components. In some examples, semiconductor wafers may include one or more epitaxial layers formed on a substrate. As used herein, an “epitaxial layer” is a single-crystal semiconductor layer grown on top of a substrate using a process called “epitaxial growth” and/or “epitaxy.” The epitaxial layer may be deposited atom-by-atom and may adopt the crystal structure of the underlying substrate. Furthermore, a “substrate” refers to a solid semiconductor material upon which epitaxial layers are formed. A substrate may be a homogenous material, such as silicon carbide and/or sapphire and may provide mechanical support for the formation of epitaxial layers. In some examples, substrates may be provided as a semiconductor wafer on which various other layers and structures are formed. By way of non-limiting example, an example epitaxial layer may have a thickness in a range of, for instance, about 0.2 microns (μm) to about 200 microns (μm), and an example substrate may have a thickness in a range of, for instance, about 0.5 microns (μm) to about 1000 microns (μm) or greater.

During the manufacturing process, one or more metallization structures may be provided on the semiconductor wafer. A “metallization structure” is any layer, structure, or other portion of a semiconductor device, semiconductor die, semiconductor package, semiconductor structure, and/or the like, that incorporates a metal for thermal and/or electrical connection. Metallization structures in a manufactured semiconductor device may be used, for instance, to provide electrically conductive and/or thermally conductive connection to the semiconductor structure. By way of non-limiting example, metallization structures may include, for instance, contacts, electrodes, interconnections, bonding pads, backside layers, metal layers, and/or metal coatings of a semiconductor device.

In some semiconductor manufacturing processes, a laser-based annealing process is used to provide metallization structures and ohmic contacts on one or more sides of the semiconductor wafer. For instance, some semiconductor devices include a metallization structure on a backside of the semiconductor device (hereinafter “backside metallization structure”) that forms an electrode (e.g., drain electrode) for the semiconductor device. Such semiconductor devices further include one or more conductive layers, such as a nickel-based and/or nickel silicide-based layer, that together with the backside metallization structure forms an ohmic contact for the semiconductor device.

However, these laser-based annealing processes may not provide a uniform temperature across the semiconductor wafer, thereby resulting in non-uniform conductive layers on the backside of the semiconductor device. More particularly, due to the non-uniform temperatures, conductive layers having different stoichiometries (e.g., Ni₂Si, NiSi₂, Ni₃Si, Ni₅Si₂, etc.) and different electrical resistivity, adhesion, and thermomechanical properties are formed. Moreover, carbon contamination and associated failures, such as cracks and backside metal peeling, likewise result from such laser-based annealing processes. Even further, laser-based annealing processes often result in interface failures at a variety of locations in the semiconductor device, such as an interface between the conductive layers and backside metallization structure, an interface between the semiconductor structure and the conductive layers, and the like.

To address the aforementioned manufacturing challenges, example aspects of the present disclosure are directed to semiconductor devices and methods for manufacturing the same that use metastable stable reactive layers, such as thermites, such as metastable nano-thermites, to facilitate near-equiatomic stoichiometry formation of conductive layers, such as metal silicide layers (e.g., nickel silicide (NiSi)). It should be understood that, as used herein, “nano-thermite” refers to thermites having a thickness and/or a grain size in a range of 1 nanometer to about 1 micron. Furthermore, as used herein, a “metastable” substance refers to a chemical and/or physical equilibrium state of that substance that is capable of transitioning (e.g., igniting) when an outside force (e.g., energy) is applied thereto.

As will be discussed in greater detail below, metastable reactive layers and thermite structures of the present disclosure may include metastable nano-thermites having a low activation energy (EA) that locally generate and self-propagate heat across one or more reactive layers of the thermite structures when energy (e.g., electrical spark, laser pulse, applied voltage, etc.) is applied thereto. The applied energy may ignite an isolated exothermic reaction in the thermite structure, which results in a prompt release of stored chemical energy in a sudden and localized discharge of high-intensity energy (e.g., light, heat). In this manner, excessive heat exposure to the semiconductor wafer may be significantly limited. It should be understood that, as used herein, “thermite layers” and “thermite structures” may be used interchangeably and refer to structures having one or more reactive layers that include metastable nano-thermites.

As will be discussed in greater detail below, thermite structures of the present disclosure may include one or more metastable reactive layers. In some examples, the one or more metastable reactive layers include one or more solid reactants of metal-metal and/or metal-metal oxide (e.g., Al/CuOₓ, Al/Pt, Ni/Al, Zr/Al/CuNi) having different enthalpies of reaction. Additionally and/or alternatively, in some examples, the one or more metastable reactive layers may include a metal silicide (e.g., Rh/Si, Nb/Si, Zr/Si, Ti/Si). For instance, an example thermite structure may include one or more metastable reactive layers having titanium silicide (Ti/Si) (e.g., having a Ti:Si ratio of 5:3) which, upon application of energy, generates an isolated exothermic reaction that forms an intermetallic titanium-silicide layer (e.g., Ti₅Si₃).

As noted above, when energy is applied to the thermite structure, a self-propagating exothermic reaction between the one or more metastable reactive layers therein is generated. More particularly, the exothermic reaction may generate high temperatures (e.g., about 800° C. to about 1500° C.) that alloy the solid reactants of the one or more metastable reactive layers. For instance, in some examples, a semiconductor structure may be provided on a substrate, and a metastable reactive layer may be provided on the semiconductor structure. As will be discussed in greater detail below, the metastable reactive layer may be provided on the semiconductor structure using any suitable deposition process, such as a sol-gel chemistry deposition process, a self-assembly deposition process, a core-shell structure deposition process, a physical vapor deposition (PVD) process (e.g., magnetron sputtering), a chemical vapor deposition (CVD) process, and the like. Energy may then be applied to the metastable reactive layer, thereby catalyzing an ignition of the metastable reactive layer that forms a silicide layer on the semiconductor structure. In some examples, a metallization structure may be provided on the silicide layer to form an ohmic contact for a semiconductor device.

As will be discussed in greater detail below, metastable reactive layers of the present disclosure may include multiple layers and/or a mixed nanoscale reductive layer of metal-metal and/or metal and metal-oxide particles and layers. For instance, in some examples, the metastable reactive layers of the present disclosure may have a thickness less than about 200 nanometers, such as a thickness in a range of about 10 nanometers to about 150 nanometers, such as a range of about 10 nanometers to about 100 nanometers, such as a thickness of about 50 nanometers. The exothermic reaction catalyzed in the metastable reactive layer may be tuned and controlled based on the chemical makeup of the metastable reactive layer itself. For instance, a reaction rate and ignition delay of the metastable reactive layer may be tuned various parameters, such as thickness, surface area, stoichiometry, particle size, packing density, doping, and the like.

Aspects of the present disclosure provide a number of technical effects and benefits. For instance, the systems and methods described herein provide uniform, controlled metallization structure formation for semiconductor devices. By catalyzing an isolated exothermic reaction in the thermite structures, excess heat exposure across other semiconductor structures (e.g., semiconductor wafers, substrates, etc.) is reduced, which likewise reduces various manufacturing-induced infirmities, such as backside metallization peeling, cracking, and the like. Similarly, failures at various interfaces in the semiconductor devices may also be reduced. Moreover, the silicide layers formed from such exothermic reactions have consistent and uniform electrical and chemical characteristics, such as electric resistivity and adhesion, as well as uniform and consistent thermomechanical properties. Furthermore, by adjusting various physical and chemical properties of the metastable reactive layers (e.g., thickness, surface area, stoichiometry, particle size, packing density, doping, etc.), example aspects of the present disclosure provide for tunable and controllable exothermic reactions.

It will be understood that, although the terms first, second, third, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, region, or substrate is referred to as being “on” or extending “onto” another element, it may be directly on or extend directly onto the other element or intervening elements may also be present. In contrast, when an element is referred to as being “directly on” or extending “directly onto” another element, there are no intervening elements present, except in some examples an attach material (e.g., die-attach material, solder, paste, adhesive, sintered material or other material may be present. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present, except in some examples an attach material (e.g., die-attach material, solder, paste, adhesive, sintered material or other material may be present.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the disclosure are described herein with reference to cross-section illustrations that are schematic illustrations of idealized embodiments of the disclosure. The thickness of layers and regions in the drawings may be exaggerated for clarity. Additionally, variations from the shapes of the illustrations as a result, for example, of manufacturing techniques and/or tolerances, are to be expected. Thus, embodiments of the disclosure should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the invention are described with reference to semiconductor layers and/or regions which are characterized as having a conductivity type such as n type or p type, which refers to the majority carrier concentration in the layer and/or region. Thus, N type material has a majority equilibrium concentration of negatively charged electrons, while P type material has a majority equilibrium concentration of positively charged holes. Some material may be designated with a “+” or “−” (as in N+, N−, P+, P−, N++, N−−, P++, P−−, or the like), to indicate a relatively larger (“+”) or smaller (“−”) concentration of majority carriers compared to another layer or region. However, such notation does not imply the existence of a particular concentration of majority or minority carriers in a layer or region.

Aspects of the present disclosure are discussed with reference to silicon carbide-based semiconductor structures, such as silicon carbide-based MOSFETs. Those of ordinary skill in the art, using the disclosures provided herein, will understand that the power semiconductor packages according to example embodiments of the present disclosure may be used with any semiconductor material, such as other wide band gap semiconductor materials, without deviating from the scope of the present disclosure. Example wide band gap semiconductor materials include silicon carbide and the Group III-nitrides.

In the drawings and specification, there have been disclosed typical embodiments and, although specific terms are employed, they are used in a generic and descriptive sense only and not for purposes of limitation of the scope set forth in the following claims.

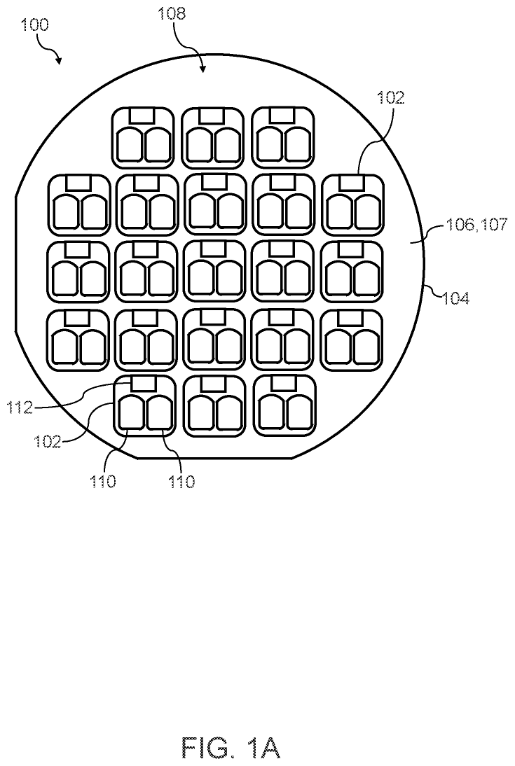

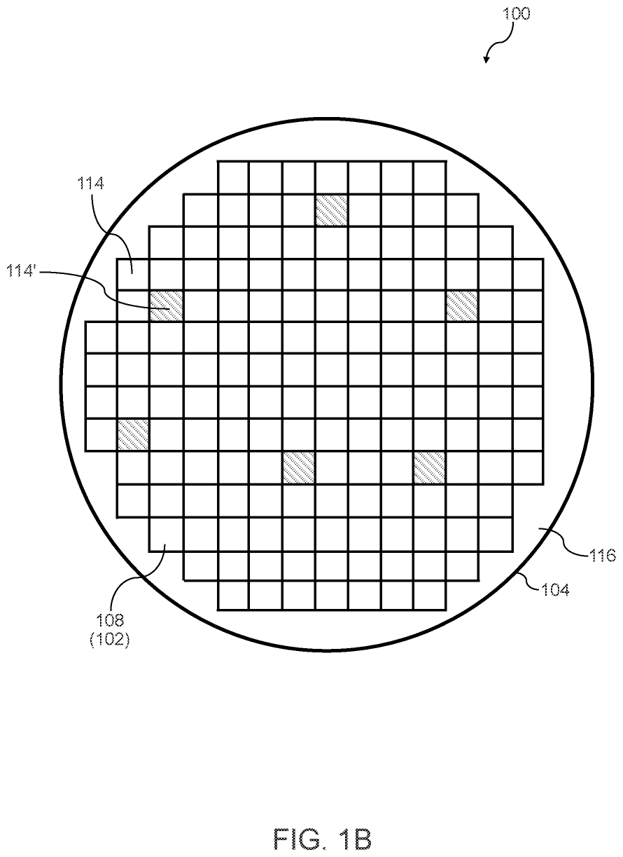

FIGS. 1A-1B depict an example semiconductor wafer 100 according to example embodiments of the present disclosure. More particularly, FIG. 1A depicts a top view of the semiconductor wafer 100, and FIG. 1B depicts a bottom view of the semiconductor wafer 100. It should be understood that FIGS. 1A-1B are intended to represent structures for purposes of identification and description and are not intended to represent the structures to physical scale.

FIG. 1A depicts a plan view of a top side 100A of the example semiconductor wafer 100. The semiconductor wafer 100 may serve as the foundation for manufacturing a plurality of semiconductor devices, such as integrated circuits (ICs) and/or other electronic components. For instance, as shown in FIG. 1A, the semiconductor wafer 100 may include a plurality of semiconductor devices 102 provided therein. The semiconductor devices 102 may be provided in rows and columns and may be spaced apart from each other such that the semiconductor wafer 100 may later be subjected to a singulation process (e.g., diced) to separate the individual semiconductor devices 102 for packaging and testing.

The semiconductor wafer 100 may be a thin, disc-shaped sheet of semiconductor material, such as silicon (Si), silicon carbide (SiC), gallium nitride (GaN), and the like. The semiconductor wafer 100 may include a semiconductor structure with other material layers, such as insulating layers and/or metal layers, provided thereon. More particularly, the semiconductor wafer 100 may include a semiconductor substrate 104. In some examples, the semiconductor wafer 100 may include one or more epitaxial layers 106, which may be a single-crystal semiconductor layer grown on a top side of the substrate 104. In some examples, the semiconductor wafer 100 may include one or more passivation layers 107 having any suitable passivation material, such as one or more silicon nitride layers, one or more polymer layers, and/or the like.

The semiconductor substrate 104 may include a semiconductor material, such as a wide bandgap semiconductor material. By way of non-limiting example, the semiconductor substrate 104 may be a silicon (Si) substrate, a silicon carbide (SiC) substrate, a Group III-nitride (e.g., gallium nitride (GaN)) substrate, a sapphire substrate, and/or other suitable substrates. In some examples, the semiconductor substrate 104 may be a SiC substrate that may include, for example, the 4H polytype of SiC or may be the 3C, 6H, and/or 15R polytypes of SiC. Other semiconductor layers (e.g., polysilicon gate layers), insulating layers, and/or metal layers may be provided on the semiconductor substrate 104 to form the plurality of semiconductor devices 102. In this manner, the semiconductor substrate 104 may be a semiconductor structure. As used herein, a “semiconductor structure” refers to a structure having one or more semiconductor layers, such as semiconductor substrates and/or semiconductor epitaxial layers.

As noted above, the semiconductor wafer 100 may be subjected to wafer-level processing and diced to form a plurality of semiconductor die 108 having one or more of the plurality of semiconductor devices 102. More particularly, each semiconductor device 102 may be spaced apart on the semiconductor wafer 100 and may include, for instance, a silicon carbide-based metal-oxide-semiconductor field-effect transistor (MOSFET), a silicon carbide-based Schottky diode, a Group-III nitride-based high electron mobility transistor (HEMT) device, and/or the like. The semiconductor wafer 100 may be cut and/or diced (e.g., using a wire saw and/or a laser) along a portion of the semiconductor wafer 100 that runs between each of the semiconductor devices 102 such that each individual cut piece becomes a semiconductor die 108 that is later packaged in a semiconductor device package (e.g., discrete semiconductor device package, power module, etc.).

In some examples, such as that depicted in FIGS. 1A-1B, the semiconductor devices 102 may include vertical structures (e.g., vertical semiconductor device units) such that each semiconductor device 102 is a vertical semiconductor device. More particularly, as will be discussed in greater detail below, each semiconductor device 102 may include at least one electrode (e.g., source electrode, gate electrode, drain electrode for a power MOSFET device) on each major side (e.g., top side 102A (FIG. 1A), bottom side 102B (FIG. 1B)) of the semiconductor structure. Additionally and/or alternatively, in other examples (not shown), the semiconductor devices 102 may include lateral structures (e.g., lateral semiconductor device units) such that each semiconductor device 102 is a lateral semiconductor device having the electrodes on the same major side of the semiconductor structure. Furthermore, as will be discussed in greater detail below, metal layer structures (e.g., metallization structures) may be provided on each side of the semiconductor devices 102 to form electrodes for the semiconductor devices 102 (e.g., source electrode 110 (FIG. 1A), gate electrode 112 (FIG. 1A), drain electrode 114 (FIG. 1B)).

FIG. 1B depicts a plan view of a bottom side 100B of the example semiconductor wafer 100 discussed above with reference to FIG. 1A. As noted above, metal layer structures may be provided on each side of the semiconductor devices 102 to form electrodes for the semiconductor devices 102. For instance, as shown in FIG. 1B, each semiconductor device 102 may include a drain electrode 114 on an opposing major side (e.g., on the backside) from the corresponding source electrode 110 (FIG. 1A) and gate electrode 112 (FIG. 1A). It should be understood that the terms “metal layer structure,” “metallization layer,” and “metallization structure” may be used interchangeably.

One or more conductive layers, such as silicide layer 116, may also be provided on the backside of each semiconductor device 102 (e.g., on bottom side 100B of the semiconductor wafer 100) that, together with the corresponding backside metallization structure (e.g., drain electrode 114), forms an ohmic contact for the semiconductor device 102. In some examples, a laser-based annealing process is used to provide the metal layers (e.g., drain electrode 114) and the silicide layer 116. However, in addition to the other issues discussed above, such laser-based annealing processes often result in interface failures at a variety of locations on the semiconductor wafer 100 and the semiconductor devices 102, such as the interface between the silicide layer 116 and the backside metallization structure (e.g., drain electrode 114). For instance, as shown in FIG. 1B, laser-based annealing processes may result in a peeling of the backside metallization structure, which is represented in FIG. 1B as inoperative drain electrodes 114′.

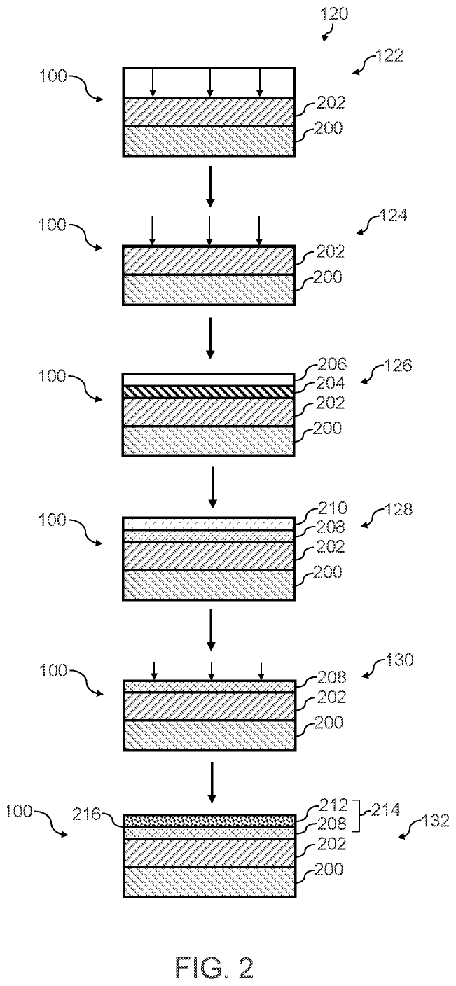

FIG. 2 depicts an overview of an example method 120 according to example embodiments of the present disclosure. As discussed below, the method 120 uses a laser-based annealing process to provide one or more metallization structures for a semiconductor device. FIG. 2 is intended to represent structures for identification and description and is not intended to represent the structures to physical scale. The method 120 includes operations illustrated in a particular order for purposes of illustration and discussion. Those having ordinary skill in the art, using the disclosures provided herein, will understand that the various steps or operations of any of the methods provided in this disclosure may be adapted, rearranged, omitted, include steps not illustrated, and/or modified in various ways without deviating from the scope of the present disclosure.

At 122, the method 120 may include providing a semiconductor structure 202 on a substrate 200. In some examples, the substrate 200 and the semiconductor structure 202 may include a wide bandgap semiconductor such as, for instance, silicon carbide (SiC), a Group III-nitride (e.g., gallium nitride (GaN)), and/or the like. Other suitable substrates and structures may be used without deviating from the scope of the present disclosure. The semiconductor structure 202 may then be thinned to a desired thickness, such as, in some examples, a thickness in a range of about 100 microns to about 1000 microns. In some examples, the substrate 200 and the semiconductor structure 202 may be provided in the form of a semiconductor wafer, such as the semiconductor wafer 100 discussed above with reference to FIGS. 1A-1B.

At 124, the method 120 may include etching the semiconductor structure 202. More particularly, layers may be removed from a surface of the semiconductor structure 202 using any suitable etching process, such as, by way of non-limiting example, any suitable wet chemical etching process and/or any suitable plasma-based dry etching process.

At 126, the method 120 may include providing (e.g., depositing) one or more layers, such as nickel (Ni) layer 204 and silicon (Si) layer 206, on the semiconductor structure 202. The nickel layer 204 and the silicon layer 206 may be provided using any suitable deposition process, such as a sol-gel chemistry deposition process, a self-assembly deposition process, a core-shell structure deposition process, a physical vapor deposition (PVD) process (e.g., magnetron sputtering), a chemical vapor deposition (CVD) process, and the like.

At 128, the method 120 may include annealing the semiconductor wafer 100. More particularly, a laser-based annealing process may be used to alloy the nickel layer 204 and the silicon layer 206, thereby forming a silicide layer 208. In the example depicted in FIG. 2, the silicide layer 208 is a nickel silicide (NiSi) layer 208. The annealing process performed at 124 may also form an oxide layer 210 on the silicide layer 208.

At 130, the method 120 may include removing the oxide layer 210 from the silicide layer 208. In some examples, the oxide layer 210 may be removed by a dry etching process, such as reactive-ion etching (RIE) and/or the like.

At 132, the method 120 may include providing a metallization layer, such as a metallization structure 212, on the silicide layer 208. It should be understood that “metallization layer” and “metallization structure” are used interchangeably herein. In some examples, such as that depicted in FIG. 2, the metallization structure 212 may be a backside metallization structure 212 for a semiconductor device, such as one of the plurality of semiconductor devices 102 depicted in FIGS. 1A-1B. The metallization structure 212 may form an electrode for the semiconductor device. For instance, in some examples, the metallization structure 212 may provide a drain electrode (e.g., drain electrode 114) for the semiconductor device. Furthermore, the metallization structure 212 and the silicide layer 208 may provide at least a part of an ohmic contact 214 for the semiconductor device. Additionally, in some examples, the metallization structure 212 may include an aluminum alloy, such as an aluminum-nickel (AlNi) alloy and/or the like. In other examples, the metallization structure may include a titanium alloy, such as a titanium-nickel-gold (TiNiAu) alloy and/or the like. Those having ordinary skill in the art will appreciate that any suitable metallization structure having any suitable composition may be used without deviating from the scope of the present disclosure.

As described above, the annealing process performed at 124 may, in some examples, provide inconsistent and non-uniform temperatures across the nickel layer 204, the silicide layer 206, and/or the semiconductor wafer 100 as a whole. As such, the resulting silicide layer 208 may not be uniform across the semiconductor wafer 100. For instance, the annealing process may result in a non-uniform silicide layer 208 having different stoichiometries (e.g., Ni₂Si, NiSi₂, Ni₃Si, Ni₅Si₂, etc.). As such, the silicide layer 208 may have inconsistent and/or different electrical resistivity, adhesion, thermomechanical properties, and the like.

Moreover, carbon contamination and other failures, such as cracking and backside metallization peeling, may also result from providing the silicide layer 208 with the annealing process at 124. For instance, in some examples, an interface 216 between the metallization structure 212 and the silicide layer 208 may fail, which may cause backside peeling of the metallization structure 212 from the silicide layer 208. Such interface failures and backside peeling may ultimately result in inoperative drain electrodes 114′ (FIG. 1B) for the semiconductor devices 102 (FIG. 1B).

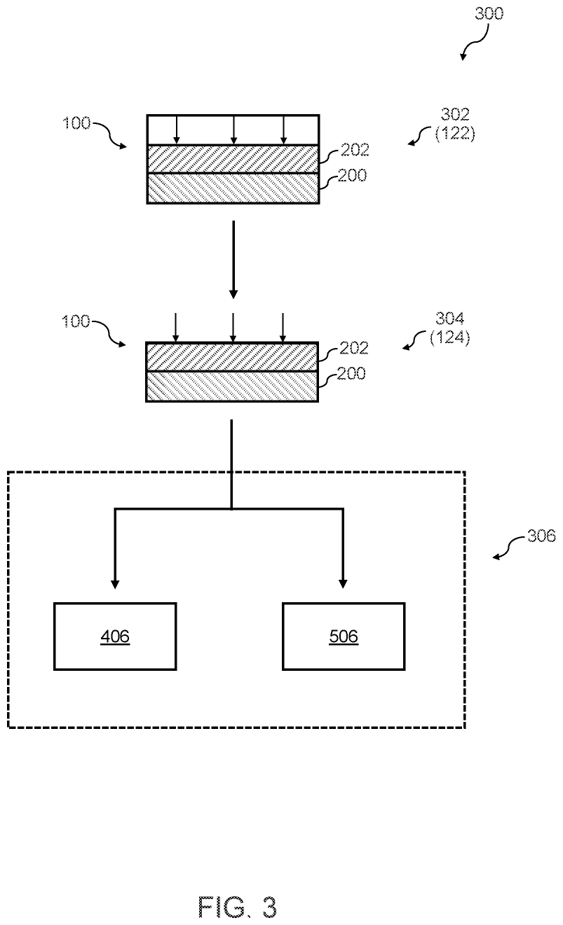

FIGS. 3-5 depict an overview of an example method 300 according to example embodiments of the present disclosure. As discussed in greater detail below, to address the laser-based annealing-related issues discussed herein, the method 300 uses a thermite-based silicide formation process. FIGS. 3-5 are intended to represent structures for identification and description and are not intended to represent the structures to physical scale. The method 300 includes operations illustrated in a particular order for purposes of illustration and discussion. Those having ordinary skill in the art, using the disclosures provided herein, will understand that the various steps or operations of any of the methods provided in this disclosure may be adapted, rearranged, omitted, include steps not illustrated, and/or modified in various ways without deviating from the scope of the present disclosure.

At 302, the method 300 may include providing the semiconductor structure 202 on the substrate 200 in the same and/or similar manner as discussed above at 122 of the method 120.

At 304, the method 300 may include etching the semiconductor structure 202 in the same and/or similar manner as discussed above at 124 of the method 120.

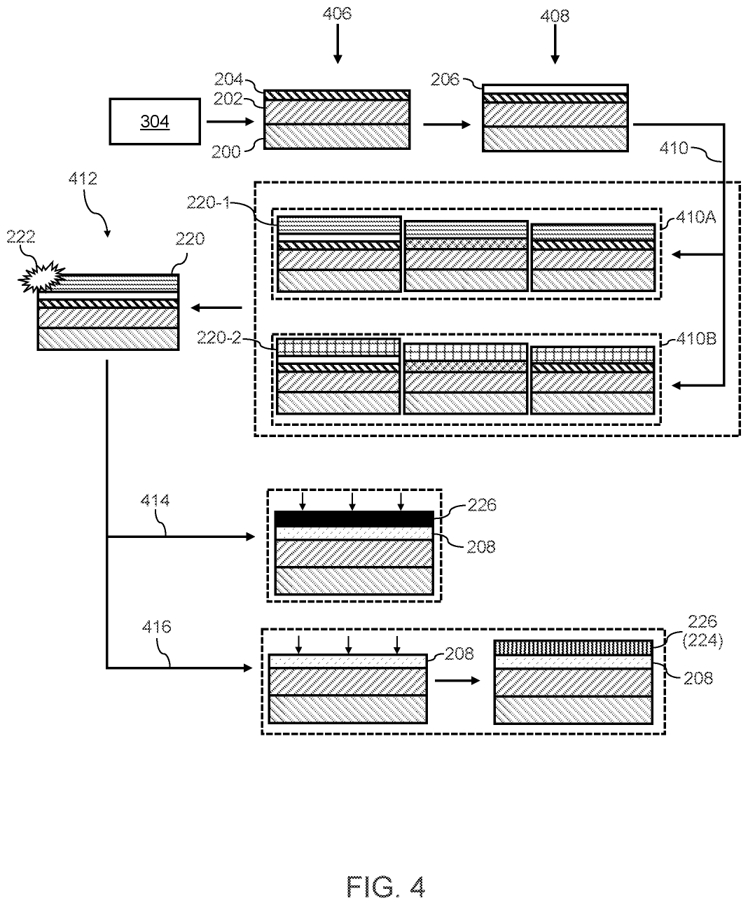

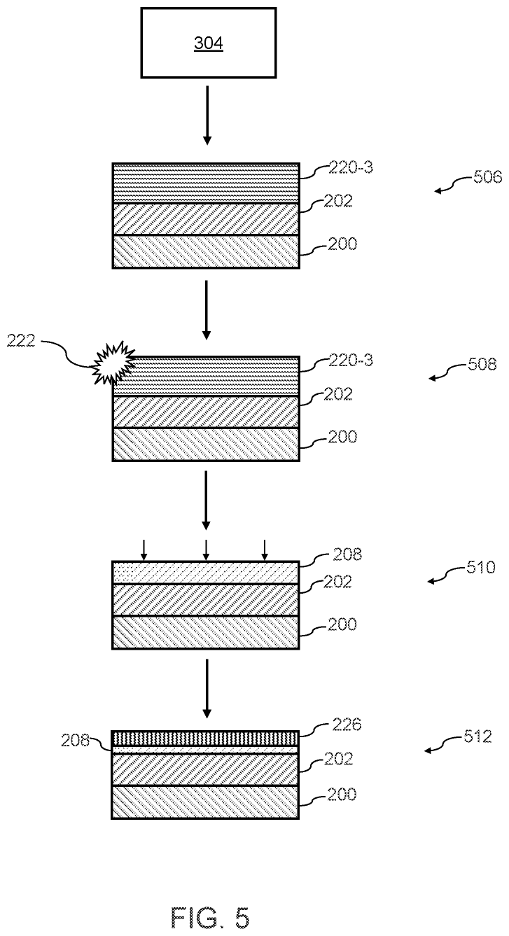

By way of non-limiting illustrative examples, following etching the semiconductor structure 202 at 304, the method 300 may proceed to the illustrative thermite-based process depicted in FIG. 4 and/or to the illustrative thermite-based process depicted in FIG. 5.

For instance, referring now to FIG. 4, the method 300 may proceed to 406. As shown in FIG. 4 at 406, the method 300 may include providing the nickel layer 204 on the semiconductor structure 202. The nickel layer 204 may be provided on the semiconductor structure 202 in the same and/or similar manner as discussed above at 126 of the method 120.

At 408, the method 300 may include providing the silicon layer 206 on the nickel layer 204. The silicon layer 206 may be provided on the nickel layer 204 in the same and/or similar manner as discussed above at 126 of the method 120.

At 410, the method 300 may include providing a metastable reactive layer 220 on the semiconductor structure 202. In some examples, the metastable reactive layer may have a thickness T in a range of about 10 nanometers to about 150 nanometers, such as a thickness T in a range of about 20 nanometers to about 100 nanometers, such as a thickness T in a range of about 30 nanometers to about 75 nanometers, such as a thickness T of about 50 nanometers.

As will be discussed in greater detail below, the metastable reactive layer 220 may include one or more nano-thermites, such as, by way of non-limiting example, aluminum-copper oxide (Al/CuO_{X}), aluminum-platinum (Al/Pt), nickel-aluminum (Ni/Al), zirconium-aluminum-cupronickel (Zr/Al/CuNi), and/or the like. Additionally and/or alternatively, in some examples, the nano-thermites may include a metal silicide, such as, by way of non-limiting example, silyrhodium (Rh/Si), niobium-silicide (Nb/Si), zirconium-silicide (Zr/Si), titanium-silicide (Ti/Si), and/or the like. In this manner, the metastable reactive layer 220 may be a thermite structure and/or a thermite layer. It should be understood that the terms “metastable reactive layer,” “thermite layer,” and/or “thermite structure” may be used interchangeably.

In some examples, such as at 410A, the metastable reactive layer 220 may be a multilayer metastable reactive structure 220-1 having a plurality of nano-thermite layers. In other examples, such as at 410B, the metastable reactive layer 220 may be a metastable reactive structure 220-2 having a plurality of co-deposited particles, such as a plurality of co-deposited nano-thermite particles. It should be understood that the metastable reactive layer 220 may have any suitable nano-thermite configuration without deviating from the scope of the present disclosure.

At 412, the method 300 may include applying energy 222 to the metastable reactive layer 220 to form the silicide layer 208 on the semiconductor structure 202. By way of non-limiting example, the energy 222 may be, for instance, an electrical spark, a laser pulse, an applied voltage, and/or the like. An amount of energy 222 applied to the metastable reactive layer 220 may be sufficient to catalyze an isolated exothermic reaction in the metastable reactive layer 220. The exothermic reaction catalyzed by energy 222 may generate heat in a range of about 800° C. to about 1500° C., which alloys the nickel layer 204 and the silicon layer 206. In this manner, the silicide layer 208 (e.g., nickel-silicide (NiSi) layer) may be provided on the semiconductor structure 202 based on the ignition catalyzed by applying the energy 222 to the metastable reactive layer 220. Hence, the silicide layer 208 may be an ignition-deposited silicide layer 208. In addition to the ignition-deposited silicide layer 208, the exothermic reaction in the metastable reactive layer 220 may also provide a metal layer 224 on the ignition-deposited silicide layer 208. Hence, in some examples, the metal layer 224 may be an ignition-deposited metal layer 224.

In some examples, following the isolated exothermic reaction in the metastable reactive layer 220 catalyzed by the applied energy 222, the method 300 may proceed to 414. At 414, the method 300 may include etching and/or polishing the ignition-deposited metal layer 224 to provide a metallization structure 226 on the ignition-deposited silicide layer 208. In some examples, the metallization structure 226 may include an aluminum alloy, such as an aluminum-nickel (AlNi) alloy. Additionally, like the metallization structure 212 discussed herein, the metallization structure 226 may be a backside metallization structure 226 and may form an electrode (e.g., drain electrode) for a semiconductor device. Hence, the metallization structure 226 provided from the ignition-deposited metal layer 224 may form an ohmic contact with the ignition-deposited silicide layer 208.

In other examples, following the isolated exothermic reaction in the metastable reactive layer 220 catalyzed by the applied energy 222, the method 300 may proceed to 416. At 416, the method 300 may include providing the metallization structure 226 on the ignition-deposited silicide layer 208. More particularly, in contrast to 414, the ignition-deposited metal layer 224 may be removed from the ignition-deposited silicide layer 208. The ignition-deposited metal layer 224 may be removed using any suitable etching process. Following the removal of the metal layer 224, the metallization structure 226 may be provided on the ignition-deposited silicide layer 208. The metallization structure 226 may be provided using any suitable deposition process. Additionally, in some examples, the metallization structure may include a titanium alloy, such as a titanium-nickel-gold (TiNiAu) alloy.

As noted above, another illustrative thermite-based process is depicted in FIG. 5. More particularly, following etching the semiconductor structure 202 at 304 (FIG. 3), the method 300 may proceed to 506 (FIG. 5). As shown in FIG. 5 at 506, the method 300 may include providing the metastable reactive layer 220 on the semiconductor structure 202. However, in contrast to the example process described above with reference to FIG. 4, the example process depicted in FIG. 5 does not include a nickel layer deposition (e.g., at 406 of FIG. 4) or a silicon layer deposition (e.g., at 408 of FIG. 4). Rather, at 506, the method 300 may include providing the metastable reactive layer 220 directly on the semiconductor structure 202. As noted above, in some examples, the metastable reactive layer 220 may be a multilayer metastable reactive layer 220-3 having a plurality of nano-thermite layers. In some examples, such as that depicted in FIG. 5, the plurality of nano-thermite layers may include a metal silicide (e.g., silyrhodium (Rh/Si), niobium-silicide (Nb/Si), zirconium-silicide (Zr/Si), titanium-silicide (Ti/Si), etc.). Hence, the metastable reactive layer 220-3 may be a multilayer thermite structure.

At 508, the method 300 may include applying the energy 222 to the metastable reactive layer 220-3 to form the silicide layer 208 on the semiconductor structure 202. The energy 222 may be applied to the metastable reactive layer 220-3 in the same and/or similar manner as described above at 412 of FIG. 4. The exothermic reaction catalyzed by energy 222 may generate heat in a range of about 800° C. to about 1500° C., which alloys the metal silicide of the metastable reactive layer 220-3, thereby providing the silicide layer 208 (e.g., titanium-silicide (Ti₅Si₃) layer) on the semiconductor structure 202.

At 510, the method 300 may include etching and/or polishing the ignition-deposited silicide layer 208. Any suitable etching and/or polishing process may be used. Furthermore, given the chemical composition of the metastable reactive layer 220-3 (e.g., metal silicide), the exothermic reaction ignited by the energy 222 applied at 508 does not form an ignition-deposited metal layer, such as the metal layer 224 described above with reference to FIG. 4.

At 512, the method 300 may include providing the metallization structure 226 on the ignition-deposited silicide layer 208. The metallization structure 226 may be provided using any suitable deposition process. Additionally, in some examples, the metallization structure may include a titanium alloy, such as a titanium-nickel-gold (TiNiAu) alloy.

FIGS. 3-5 depict example thermite-based metallization formation processes for purposes of illustration and discussion. Those having ordinary skill in the art, using the disclosures provided herein, will understand that different thermite-based metallization formation processes may be used without deviating from the scope of the present disclosure. Furthermore, those having ordinary skill in the art, using the disclosures provided herein, will understand that the example method 300 described above with reference to FIGS. 3-5 may be performed at the wafer level (e.g., before dicing the semiconductor wafer 100 (FIGS. 1A-1B)) and/or at the die level (e.g., after dicing the semiconductor wafer 100 (FIGS. 1A-1B)).

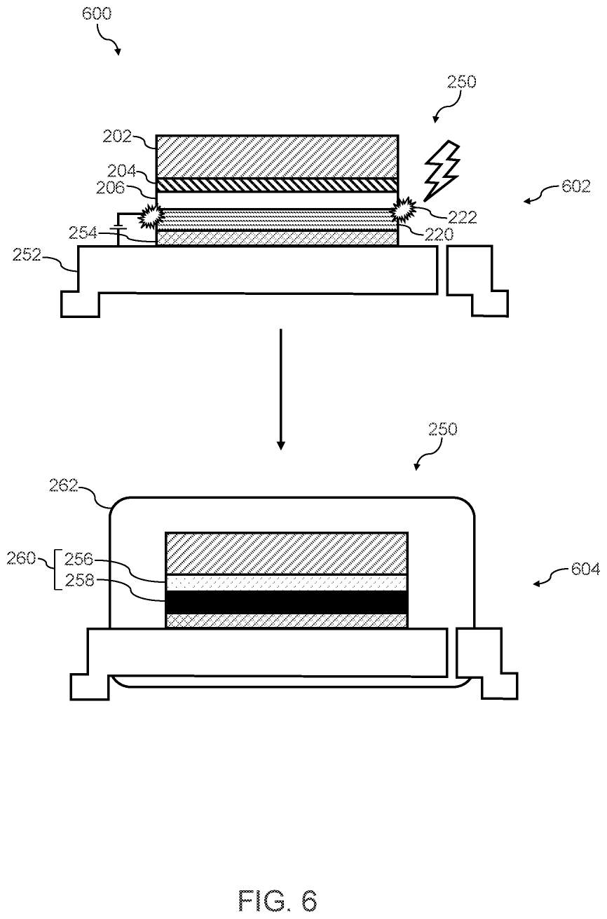

Referring now to FIG. 6, an overview of an example reactive bonding method 600 for an example semiconductor device package 250 is depicted according to example embodiments of the present disclosure. FIG. 6 is intended to represent structures for identification and description and is not intended to represent the structures to physical scale. The method 600 includes operations illustrated in a particular order for purposes of illustration and discussion. Those having ordinary skill in the art, using the disclosures provided herein, will understand that the various steps or operations of any of the methods provided in this disclosure may be adapted, rearranged, omitted, include steps not illustrated, and/or modified in various ways without deviating from the scope of the present disclosure.

At 602, the method 600 may include providing the semiconductor device package 250. In some examples, the semiconductor device package 250 may be a discrete semiconductor device package. In some examples, the semiconductor device package 250 may be a power module. However, it should be understood that the semiconductor device package 250 may be any suitable semiconductor device package without deviating from the scope of the present disclosure. In the example depicted in FIG. 6, the semiconductor device package 250 may provided with a metastable reactive layer (e.g., the metastable reactive layer 220), a silicon layer (e.g., silicon layer 206) on the metastable reactive layer 220, a nickel layer (e.g., nickel layer 204) on the silicon layer 206, and a semiconductor structure (e.g., semiconductor structure 202) on the nickel layer 204. The semiconductor device package 250 may further include a submount 252, such as a direct bonded copper (DBC) substrate, an active metal brazed (AMB) substrate, and/or the like. In some examples, the submount 252 may include a lead frame for the semiconductor device package 250. Furthermore, as will be discussed below, a die-attach material 254 may be provided between the metastable reactive layer 220 and the submount 252.

At 604, the method 600 may include applying energy 222 to the metastable reactive layer 220. More particularly, following the application of energy 222 to the metastable reactive layer 220 (e.g., nano-thermite structure), an isolated exothermic reaction may be catalyzed between the submount 252 and the semiconductor structure 202 that alloys the nickel layer 204 and the silicon layer 206 in a similar manner as described above (e.g., FIGS. 3-5). As such, following the ignition of the metastable reactive layer 220, the semiconductor structure 202 may include a metastable-reactive-layer-deposited silicide 256. In some examples, the metastable-reactive-layer-deposited silicide 256 may include nickel silicide (NiSi). Moreover, the ignition of the metastable reactive layer 220 may also form a metallization layer 258 on the metastable-reactive-layer-deposited silicide 256. The metallization layer 258 may be similar to the metallization structure 226 described above (e.g., FIGS. 3-5). Hence, an ohmic contact 260 for the semiconductor device package 250 may be formed based on the ignition of the metastable reactive layer 220.

In addition to providing the ohmic contact 260 (e.g., metastable-reactive-layer-deposited silicide 256 and metallization layer 258), the isolated exothermic reaction may also fuse the die-attach material 254 to the metallization layer 258. In this way, the die-attach material 254 may couple the metallization layer 258 to the submount 252. Additionally, because the semiconductor device package 250 is pre-fabricated (e.g., prior to the application of energy 222 that forms the ohmic contact 260), the semiconductor structure 202 may include nano-thermite residue (not shown) following the ignition. In some examples, the semiconductor device package 250 may further include an encapsulating portion 262, such as an epoxy mold compound (EMC). In some examples, the encapsulating portion 262 may directly contact the metastable-reactive-layer-deposited silicide 256 and the metallization layer 258.

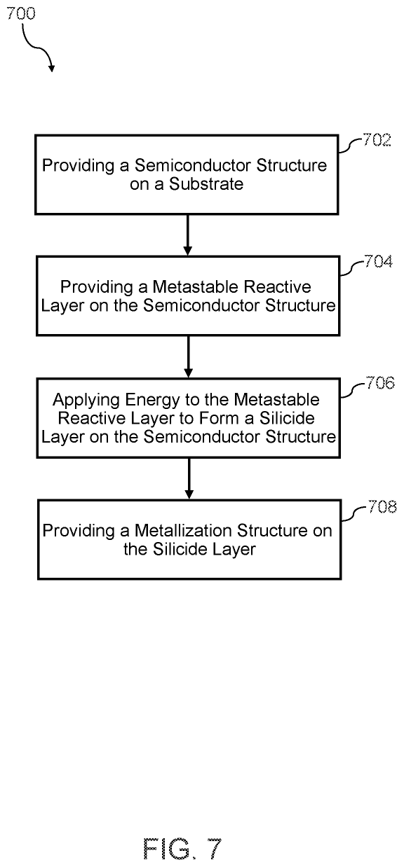

FIG. 7 depicts a flow chart diagram of an example method 700 according to example embodiments of the present disclosure. FIG. 7 depicts example process steps for purposes of illustration and discussion. Those having ordinary skill in the art, using the disclosures provided herein, will understand that the process steps of any of the methods described in the present disclosure may be adapted, modified, include steps not illustrated, omitted, and/or rearranged without deviating from the scope of the present disclosure.

At 702, the method 700 includes providing a semiconductor structure on a substrate. In some examples, the semiconductor structure may be a wide bandgap semiconductor structure, such as silicon carbide (SiC), a Group III-nitride (e.g., gallium nitride (GaN)), and/or the like.

At 704, the method 700 includes providing a metastable reactive layer on the semiconductor structure. As described above with reference to FIGS. 4-6, the metastable reactive layer may have a thickness in a range of about 10 nanometers to about 150 nanometers, such as a thickness in a range of about 20 nanometers to about 100 nanometers, such as a thickness in a range of about 30 nanometers to about 75 nanometers, such as a thickness of about 50 nanometers. Furthermore, the metastable reactive layer may include one or more nano-thermites. For instance, in some examples, the one or more nano-thermites may include aluminum-copper oxide (Al/CuO_{X}), aluminum-platinum (Al/Pt), palladium-aluminum (Pd/Al), nickel-aluminum (Ni/Al), zirconium-aluminum-cupronickel (Zr/Al/CuNi), and/or the like. Additionally and/or alternatively, in some examples, the one or more nano-thermites may include a metal silicide, such as silylrhodium (Rh/Si), a niobium-silicide (Nb/Si), a zirconium-silicide (Zr/Si), a titanium-silicide (Ti/Si), and/or the like.

In some examples, the metastable reactive layer may include a plurality of co-deposited particles. Additionally and/or alternatively, the metastable reactive layer may be a multilayer metastable reactive structure having a plurality of reactive layers, such as a plurality of nano-thermite layers.

In some examples (e.g., FIGS. 3-4), a nickel layer may be provided on the semiconductor structure, a silicon layer may be provided on the nickel layer, and the metastable reactive layer may be provided on the silicon layer. In some examples (e.g., FIG. 7), the metastable reactive layer may be provided directly on the semiconductor structure.

At 706, the method 700 includes applying energy to the metastable reactive layer to form a silicide layer on the semiconductor structure. As described above with reference to FIGS. 4-6, energy (e.g., electrical spark, laser pulse, applied voltage, etc.) may be applied to the metastable reactive layer (e.g., provided at 704) to form a silicide layer (e.g., a nickel-silicide (NiSi) layer, a titanium silicide (TiSi) layer, etc.). The applied energy may ignite an isolated exothermic reaction in the metastable layer (e.g., provided at 704) that generates heat in a range of about 800° C. to about 1500° C. In this manner, the silicide layer may be formed on the semiconductor structure based on the ignition. Additionally, in some examples, a metal layer (e.g., aluminum alloy) may be formed on the silicide layer based on the ignition.

At 708, the method 700 includes providing a metallization structure on the silicide layer. The metallization structure may be a backside metallization structure for a semiconductor device and may form an electrode (e.g., drain electrode and/or drain contact) for the semiconductor device. More particularly, as described above with reference to FIGS. 4-6, the metallization structure and the silicide layer may form an ohmic for the semiconductor device. In some examples (e.g., FIG. 4), a metal layer (e.g., the metal layer formed based on the ignition at 706) may be removed from the silicide layer, and the metallization structure may be provided on the silicide layer.

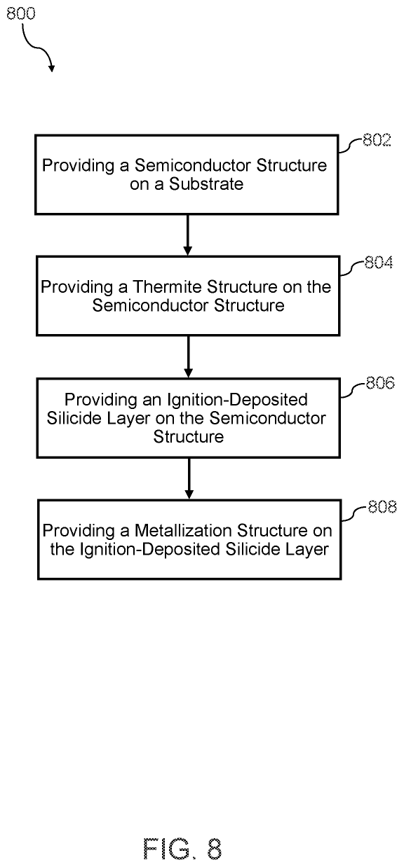

FIG. 8 depicts a flow chart diagram of an example method 800 according to example embodiments of the present disclosure. FIG. 8 depicts example process steps for purposes of illustration and discussion. Those having ordinary skill in the art, using the disclosures provided herein, will understand that the process steps of any of the methods described in the present disclosure may be adapted, modified, include steps not illustrated, omitted, and/or rearranged without deviating from the scope of the present disclosure.

At 802, the method 800 includes providing a semiconductor structure on a substrate.

At 804, the method 800 includes providing a thermite structure on the semiconductor structure. More particularly, a thermite structure, such as any of metastable reactive layers described herein, may be provided on the semiconductor structure. The thermite structure may have a thickness in a range of about 10 nanometers to about 150 nanometers, such as a thickness in a range of about 20 nanometers to about 100 nanometers, such as a thickness in a range of about 30 nanometers to about 75 nanometers, such as a thickness of about 50 nanometers. Furthermore, the thermite structure may include one or more nano-thermites, such as any of the nano-thermites described herein. In some examples, the thermite structure may include a plurality of co-deposited particles. Additionally and/or alternatively, the thermite structure may be a multilayer thermite structure having a plurality of reactive layers, such as a plurality of nano-thermite layers. In some examples (e.g., FIGS. 3-4), a nickel layer may be provided on the semiconductor structure, a silicon layer may be provided on the nickel layer, and the thermite structure may be provided on the silicon layer. In some examples (e.g., FIG. 7), the thermite structure may be provided directly on the semiconductor structure.

At 806, the method 800 includes providing an ignition-deposited silicide layer on the semiconductor structure. As described herein, the ignition-deposited silicide layer may include, for instance, a nickel-silicide (NiSi) layer (e.g., FIGS. 4, 6), titanium silicide (Ti₅Si₂) (e.g., FIG. 5), and/or the like. Furthermore, the ignition-deposited silicide layer may be provided on the semiconductor structure by catalyzing an ignition of the thermite structure with an applied energy (e.g., electrical spark, laser pulse, applied voltage, etc.), which catalyzes an isolated exothermic reaction in the thermite structure. In this manner, the ignition-deposited silicide layer may be provided on the semiconductor structure based on the ignition. Furthermore, in some examples, an ignition-deposited metal layer may also be provided on the ignition-deposited silicide layer based on the ignition.

At 808, the method 800 includes providing a metallization structure on the ignition-deposited silicide layer. As described herein, the metallization structure may be a backside metallization structure for a semiconductor device and may form an electrode (e.g., drain electrode and/or drain contact) for the semiconductor device. Hence, the metallization structure and the ignition-deposited silicide layer may form an ohmic contact for a semiconductor device. In some examples, the metallization structure may be formed from the ignition-deposited metal layer and provided on the ignition-deposited silicide layer. In some examples, the ignition-deposited metal layer may be removed from the ignition-deposited silicide layer, and the metallization structure may be provided on the ignition-deposited silicide layer in place of the ignition-deposited metal layer.

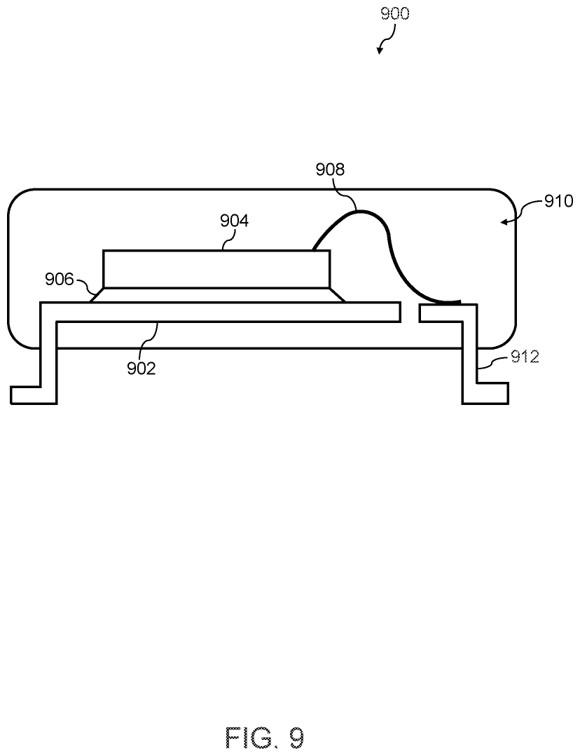

FIG. 9 depicts an example semiconductor package 900 of a semiconductor device according to example embodiments of the present disclosure. The semiconductor package 900 may be, for instance, a discrete semiconductor package. FIG. 9 is provided for purposes of illustration and discussion. Those having ordinary skill in the art, using the disclosures provided herein, will understand that aspects of the present disclosure may be used in a variety of devices and/or applications without deviating from the scope of the present disclosure. Furthermore, FIG. 9 is intended to represent structures for identification and description and is not intended to represent the structures to physical scale.

As shown, the semiconductor package 900 may include a conductive submount 902 (e.g., a patterned conductive substrate, lead frame, clip structure or other power substrate) on which a semiconductor die 904 containing one or more power devices (e.g., transistors, diodes, etc.) is attached using a die-attach material 906. It should be understood that the semiconductor die 904 may correspond to any of the semiconductor die disclosed herein and may be fabricated using any of the methods disclosed herein.

The die-attach material 906 may provide a thermal, mechanical, and electrical connection between the semiconductor die 904 and the conductive submount 902. In some examples, the semiconductor die 904 may also be connected to the conductive submount 902 using wire bonds 908. An encapsulating material 910 (e.g., epoxy mold compound (EMC)) may fill the space around the semiconductor die 904 and the submount 902, thereby forming a housing. The semiconductor package 900 may further include one or more connection structures, such as electrical leads 912, that extend outward from the housing (e.g., outward from the encapsulating material 910).

The semiconductor package 900 may include one or more metallization structures, such as any of the metallization structures disclosed herein. More particularly, the semiconductor die 904 may include one or more metallization structures, such as bonding pads. The bonding pads may be coupled to the one or more electrical leads 912 using the wire bonds 908. The wire bonds 908 may be aluminum and/or copper. The wire bonds 908 may have a thickness of about 15 mil to about 20 mil (e.g., about 381 μm to about 508 μm). As noted above, the bonding pads may have a thickness, for instance, of about 4 μm or less. A backside metallization layer on the semiconductor die 904 may be coupled to the submount 902 (e.g., lead frame) using, for instance, the die-attach material 906. The backside metallization layer may correspond to any of the backside metallization structures disclosed herein and may be provided using any of the methods and processes disclosed herein. The encapsulating material 910 may encapsulate the semiconductor die 904, including its metallization structures, wire bonds 908, submount 902, and other portions of the semiconductor package 900. In some examples, the encapsulating material 910 may directly contact the metallization structures (e.g., bonding pads, backside metallization layer, etc.) of the semiconductor package 900.

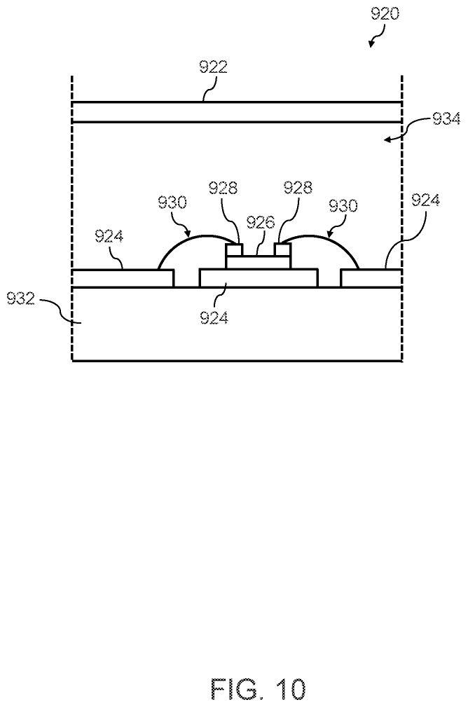

FIG. 10 depicts a cross-sectional view of an example semiconductor package of a semiconductor device 920 according to example embodiments of the present disclosure. The semiconductor device 920 of FIG. 10 is a portion of a power module. FIG. 10 is intended to represent structures for identification and description and is not intended to represent the structures to physical scale. The semiconductor device 920 may include a housing 922. The semiconductor device 920 may include a conductive submount 924 (e.g., a patterned conductive submount) on which a semiconductor die 926 is mounted (e.g., using a die-attach material). It should be understood that the semiconductor die 926 may correspond to any of the semiconductor die disclosed herein and may be fabricated using any of the methods disclosed herein. For instance, the semiconductor die 926 may be mounted on submount 924 using a die-attach material that includes a sintered material, such as sintered silver and/or sintered copper. The semiconductor die 926 may include one or more metallization structures, such as bonding pads 928 and backside metallization structures (not shown) on an opposing side of the semiconductor die 926 from the bonding pads 928. It should be understood that the one or more metallization structures may correspond to any of the metallization structures described herein and may be provided using any of the methods and processes described herein. In some embodiments, the semiconductor die 926 may be connected to the conductive submount 924 using wire bonds 930. The conductive submount 924 may be mounted on a base layer 932 (e.g., an insulating layer). An inert gel 934 may fill the space between the semiconductor die 926 and the housing 922.

FIGS. 9-10 depict example semiconductor packages for purposes of illustration and discussion. Those of ordinary skill in the art, using the disclosures provided herein, will understand that different semiconductor package configurations may be used without deviating from the scope of the present disclosure.

Example aspects of the present disclosure are set forth below. Any of the below features or examples may be used in combination with any of the embodiments or features provided in the present disclosure.

One example aspect of the present disclosure is directed to a method. The method includes providing a semiconductor structure on a substrate. The method includes providing a metastable reactive layer on the semiconductor structure. The method includes applying energy to the metastable reactive layer to form a silicide layer on the semiconductor structure.

In some examples, applying the energy to the metastable reactive layer to form the silicide layer on the semiconductor structure includes catalyzing an ignition of the metastable reactive layer with the energy and providing the silicide layer on the semiconductor structure based on the ignition.

In some examples, applying the energy to the metastable reactive layer to form the silicide layer on the semiconductor structure further includes providing a metal layer on the silicide layer based on the ignition.

In some examples, the metal layer includes an aluminum alloy.

In some examples, the aluminum alloy is an aluminum-nickel (AlNi) alloy.

In some examples, the method further includes providing a metallization structure on the silicide layer.

In some examples, providing the metallization structure on the silicide layer includes removing a metal layer from the silicide layer and providing the metallization structure on the silicide layer.

In some examples, the metallization structure includes a titanium alloy.

In some examples, the titanium alloy is a titanium-nickel-gold (TiNiAu) alloy.

In some examples, the metallization structure is a backside metallization structure for a semiconductor device.

In some examples, the metallization structure forms an electrode for a semiconductor device.

In some examples, the electrode is a drain contact for the semiconductor device.

In some examples, the metallization structure and the silicide layer form an ohmic contact for a semiconductor device.

In some examples, the energy is one of an electrical spark, a laser pulse, or an applied voltage.

In some examples, the energy catalyzes an isolated exothermic reaction in the metastable reactive layer.

In some examples, the isolated exothermic reaction generates heat in a range of about 800° C. to about 1500° C.

In some examples, the silicide layer includes a nickel-silicide (NiSi) layer.

In some examples, the silicide layer includes titanium silicide (Ti₅Si₃).

In some examples, providing the metastable reactive layer on the semiconductor structure includes providing a multilayer metastable reactive structure on the semiconductor structure.

In some examples, the multilayer metastable reactive structure includes a plurality of nano-thermite layers.

In some examples, the plurality of nano-thermite layers include a metal silicide.

In some examples, the metastable reactive layer includes a plurality of co-deposited particles.

In some examples, the metastable reactive layer includes one or more nano-thermites.

In some examples, the one or more nano-thermites include one of aluminum-copper oxide (Al/CuO_{X}), aluminum-platinum (Al/Pt), palladium-aluminum (Pd/Al), nickel-aluminum (Ni/Al), or zirconium-aluminum-cupronickel (Zr/Al/CuNi).

In some examples, the one or more nano-thermites include a metal silicide.

In some examples, the metal silicide includes one of silylrhodium (Rh/Si), a niobium-silicide (Nb/Si), a zirconium-silicide (Zr/Si), or a titanium-silicide (Ti/Si).

In some examples, the metastable reactive layer has a thickness in a range of about 10 nanometers to about 150 nanometers.

In some examples, providing the metastable reactive layer on the semiconductor structure includes providing a nickel layer on the semiconductor structure, providing a silicon layer on the nickel layer, and providing the metastable reactive layer on the silicon layer.

In some examples, providing the metastable reactive layer on the semiconductor structure includes providing the metastable reactive layer directly on the semiconductor structure.

In some examples, the semiconductor structure is a wide bandgap semiconductor structure.

In some examples, the wide bandgap semiconductor structure includes one of silicon carbide or a Group-III nitride.

Another example aspect of the present disclosure is directed to a method. The method includes providing a semiconductor structure on a substrate. The method includes providing a thermite structure on the semiconductor structure. The method includes providing an ignition-deposited silicide layer on the semiconductor structure. The method includes providing a metallization structure on the ignition-deposited silicide layer.

In some examples, the thermite structure is a multilayer thermite structure including a plurality of nano-thermite layers.

In some examples, the plurality of nano-thermite layers include a metal silicide.

In some examples, the thermite structure includes a plurality of co-deposited particles.

In some examples, the thermite structure includes one or more nano-thermites.

In some examples, the one or more nano-thermites include one of aluminum-copper oxide (Al/CuO_{X}), aluminum-platinum (Al/Pt), palladium-aluminum (Pd/Al), nickel-aluminum (Ni/Al), or zirconium-aluminum-cupronickel (Zr/Al/CuNi).

In some examples, the one or more nano-thermites include a metal silicide.

In some examples, the metal silicide includes one of silylrhodium (Rh/Si), a niobium-silicide (Nb/Si), a zirconium-silicide (Zr/Si), or a titanium-silicide (Ti/Si).

In some examples, providing the ignition-deposited silicide layer on the semiconductor structure includes catalyzing an ignition of the thermite structure with an applied energy and providing the ignition-deposited silicide layer on the semiconductor structure based on the ignition.

In some examples, providing the ignition-deposited silicide layer on the semiconductor structure further includes providing an ignition-deposited metal layer on the ignition-deposited silicide layer based on the ignition.

In some examples, providing the metallization structure on the ignition-deposited silicide layer includes providing the metallization structure on the ignition-deposited silicide layer from the ignition-deposited metal layer.

In some examples, the metallization structure includes an aluminum-nickel (AlNi) alloy.

In some examples, providing the metallization structure on the ignition-deposited silicide layer includes removing the ignition-deposited metal layer and providing the metallization structure on the ignition-deposited silicide layer.

In some examples, the metallization structure includes a titanium alloy.

In some examples, the titanium alloy is a titanium-nickel-gold (TiNiAu) alloy.

In some examples, the applied energy is one of an electrical spark, a laser pulse, or an applied voltage.

In some examples, the applied energy catalyzes an isolated exothermic reaction in the thermite structure.

In some examples, the isolated exothermic reaction generates heat in a range of about 800° C. to about 1500° C.

In some examples, the ignition-deposited silicide layer includes a nickel-silicide (NiSi) layer.

In some examples, the ignition-deposited silicide layer includes titanium silicide (Ti₅Si₃).

In some examples, providing the thermite structure on the semiconductor structure includes providing a nickel layer on the semiconductor structure, providing a silicon layer on the nickel layer, and providing the thermite structure on the silicon layer.

In some examples, providing the thermite structure on the semiconductor structure includes providing the thermite structure directly on the semiconductor structure.

In some examples, the metallization structure is a backside metallization structure for a semiconductor device.

In some examples, the metallization structure forms an electrode for a semiconductor device.

In some examples, the electrode is a drain electrode for the semiconductor device.

In some examples, the metallization structure and the ignition-deposited silicide layer form an ohmic contact for a semiconductor device.

In some examples, the thermite structure has a thickness in a range of about 10 nanometers to about 150 nanometers.

In some examples, the semiconductor structure is a wide bandgap semiconductor structure including one of silicon carbide or a Group-III nitride.

Another example aspect of the present disclosure is directed to a semiconductor device package. The semiconductor device package includes a submount, a semiconductor structure having a metastable-reactive-layer-deposited silicide, and a metallization layer on the metastable-reactive-layer-deposited silicide. The metallization layer is between the submount and the semiconductor structure.

In some examples, the semiconductor device package further includes nano-thermite residue on the semiconductor structure.

In some examples, the metastable-reactive-layer-deposited silicide and the metallization layer are formed based on an isolated exothermic reaction between the submount and the semiconductor structure.

In some examples, the isolated exothermic reaction is catalyzed by energy applied to a nano-thermite structure between the submount and the semiconductor structure, the energy being one of an electrical spark, a laser pulse, or an applied voltage.

In some examples, the nano-thermite structure includes one or more metastable nano-thermites.

In some examples, the one or more metastable nano-thermites include one of aluminum-copper oxide (Al/CuO_{X}), aluminum-platinum (Al/Pt), palladium-aluminum (Pd/Al), nickel-aluminum (Ni/Al), or zirconium-aluminum-cupronickel (Zr/Al/CuNi).

In some examples, the one or more metastable nano-thermites include one of silylrhodium (Rh/Si), a niobium-silicide (Nb/Si), a zirconium-silicide (Zr/Si), or a titanium-silicide (Ti/Si).

In some examples, the semiconductor device package further includes a die-attach material coupling the metallization layer to the submount.

In some examples, the isolated exothermic reaction fuses the die-attach material to the metallization layer.

In some examples, the metastable-reactive-layer-deposited silicide includes nickel silicide (NiSi).

In some examples, the metastable-reactive-layer-deposited silicide and the metallization layer form an ohmic contact for the semiconductor structure.

In some examples, the metallization layer includes an aluminum-nickel (AlNi) alloy.

In some examples, the metallization layer includes a titanium-nickel-gold (TiNiAu) alloy.

In some examples, the metallization layer is a backside metallization structure for the semiconductor device package.

In some examples, the backside metallization structure is a drain electrode for the semiconductor structure.

In some examples, the semiconductor device package further includes an encapsulating portion.

In some examples, the encapsulating portion directly contacts the metastable-reactive-layer-deposited silicide and the metallization layer.

In some examples, the encapsulating portion includes an epoxy mold compound (EMC).

In some examples, the semiconductor device package further includes a passivation layer on the semiconductor structure.

In some examples, the passivation layer includes one of silicon nitride or a polymer.

In some examples, the semiconductor structure includes a wide bandgap semiconductor.

In some examples, the semiconductor structure includes one of a silicon carbide-based metal-oxide-semiconductor field-effect transistor (MOSFET), a silicon carbide-based Schottky diode, or a Group-III nitride-based high electron mobility transistor (HEMT) device.

In some examples, the semiconductor device package is one of a discrete semiconductor device package or a power module.

In some examples, the submount includes one of a direct bonded copper (DBC) substrate or an active metal brazed (AMB) substrate.

In some examples, the submount includes a lead frame for the semiconductor device package.

Another example aspect of the present disclosure is directed to a semiconductor die. The semiconductor die includes a metastable-reactive-layer-deposited silicide and a metallization layer on the metastable-reactive-layer-deposited silicide.

In some examples, the semiconductor die further includes nano-thermite residue on the metastable-reactive-layer-deposited silicide.

In some examples, the metastable-reactive-layer-deposited silicide and the metallization layer form an ohmic contact for the semiconductor die.

In some examples, the metastable-reactive-layer-deposited silicide and the metallization layer are formed based on an isolated exothermic reaction on the semiconductor die catalyzed by energy applied to a nano-thermite structure on the semiconductor die, the energy being one of an electrical spark, a laser pulse, or an applied voltage.

In some examples, the nano-thermite structure includes one or more metastable nano-thermites.

In some examples, the one or more metastable nano-thermites include one of aluminum-copper oxide (Al/CuO_{X}), aluminum-platinum (Al/Pt), palladium-aluminum (Pd/Al), nickel-aluminum (Ni/Al), or zirconium-aluminum-cupronickel (Zr/Al/CuNi).

In some examples, the one or more metastable nano-thermites include one of silylrhodium (Rh/Si), a niobium-silicide (Nb/Si), a zirconium-silicide (Zr/Si), or a titanium-silicide (Ti/Si).

In some examples, the metastable-reactive-layer-deposited silicide includes nickel silicide (NiSi).

In some examples, the metallization layer includes one of an aluminum-nickel (AlNi) alloy or a titanium-nickel-gold (TiNiAu) alloy.

In some examples, the metallization layer forms an electrode for a semiconductor device, the semiconductor device being one of a discrete semiconductor device or a power module.

In some examples, the semiconductor die includes a wide bandgap semiconductor, the wide bandgap semiconductor including one of silicon carbide or a Group-III nitride.

In some examples, the semiconductor die includes one of a silicon carbide-based metal-oxide-semiconductor field-effect transistor (MOSFET), a silicon carbide-based Schottky diode, or a Group-III nitride-based high electron mobility transistor (HEMT) device.

Another example aspect of the present disclosure is directed to a semiconductor wafer. The semiconductor wafer includes a semiconductor substrate, a metastable-reactive-layer-deposited silicide on the semiconductor substrate, and a metallization layer on the metastable-reactive-layer-deposited silicide.

In some examples, the semiconductor wafer further includes nano-thermite residue on the semiconductor substrate.

In some examples, the semiconductor wafer is diced into a plurality of semiconductor die.

In some examples, the metastable-reactive-layer-deposited silicide and the metallization layer form one or more ohmic contacts for each of the plurality of semiconductor die.

In some examples, the metastable-reactive-layer-deposited silicide and the metallization layer are formed based on an isolated exothermic reaction on the semiconductor wafer catalyzed by energy applied to a nano-thermite structure on the semiconductor wafer, the energy being one of an electrical spark, a laser pulse, or an applied voltage.

In some examples, the nano-thermite structure includes one or more metastable nano-thermites.

In some examples, the one or more metastable nano-thermites include one of aluminum-copper oxide (Al/CuO_{X}), aluminum-platinum (Al/Pt), palladium-aluminum (Pd/Al), nickel-aluminum (Ni/Al), or zirconium-aluminum-cupronickel (Zr/Al/CuNi).

In some examples, the one or more metastable nano-thermites include one of silylrhodium (Rh/Si), a niobium-silicide (Nb/Si), a zirconium-silicide (Zr/Si), or a titanium-silicide (Ti/Si).

In some examples, the metastable-reactive-layer-deposited silicide includes nickel silicide (NiSi).

In some examples, the metallization layer includes one of an aluminum-nickel (AlNi) alloy or a titanium-nickel-gold (TiNiAu) alloy.

In some examples, the metallization layer forms an electrode for a semiconductor die diced from the semiconductor wafer.

In some examples, the semiconductor die includes one of a silicon carbide-based metal-oxide-semiconductor field-effect transistor (MOSFET), a silicon carbide-based Schottky diode, or a Group-III nitride-based high electron mobility transistor (HEMT) device.

In some examples, the semiconductor substrate includes a wide bandgap semiconductor, the wide bandgap semiconductor including one of silicon carbide or a Group-III nitride.

While the present subject matter has been described in detail with respect to specific example embodiments thereof, it will be appreciated that those skilled in the art, upon attaining an understanding of the foregoing can readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. A method, comprising:
providing a semiconductor structure on a substrate;
providing a metastable reactive layer on the semiconductor structure; and
applying energy to the metastable reactive layer to form a silicide layer on the semiconductor structure.

2. The method of claim 1, wherein applying the energy to the metastable reactive layer to form the silicide layer on the semiconductor structure comprises:
catalyzing an ignition of the metastable reactive layer with the energy; and
providing the silicide layer on the semiconductor structure based on the ignition.

3. The method of claim 2, wherein applying the energy to the metastable reactive layer to form the silicide layer on the semiconductor structure further comprises:
providing a metal layer on the silicide layer based on the ignition,
wherein the metal layer comprises an aluminum alloy.

4. The method of claim 1, further comprising:
providing a metallization structure on the silicide layer.

5. The method of claim 4, wherein providing the metallization structure on the silicide layer comprises:
removing a metal layer from the silicide layer; and
providing the metallization structure on the silicide layer,
wherein the metallization structure comprises a titanium alloy.

6. The method of claim 4, wherein the metallization structure and the silicide layer form an ohmic contact for a semiconductor device.

7. The method of claim 1, wherein the energy is one of an electrical spark, a laser pulse, or an applied voltage, and wherein the energy catalyzes an isolated exothermic reaction in the metastable reactive layer.

8. The method of claim 1, wherein providing the metastable reactive layer on the semiconductor structure comprises:
providing a nickel layer on the semiconductor structure;
providing a silicon layer on the nickel layer; and
providing the metastable reactive layer on the silicon layer.

9. A method, comprising:
providing a semiconductor structure on a substrate;
providing a thermite structure on the semiconductor structure;
providing an ignition-deposited silicide layer on the semiconductor structure; and
providing a metallization structure on the ignition-deposited silicide layer.

10. The method of claim 9, wherein providing the ignition-deposited silicide layer on the semiconductor structure comprises:
catalyzing an ignition of the thermite structure with an applied energy; and
providing the ignition-deposited silicide layer on the semiconductor structure based on the ignition,
wherein the ignition-deposited metal layer is provided on the ignition-deposited silicide layer based on the ignition.

11. The method of claim 10, wherein providing the metallization structure on the ignition-deposited silicide layer comprises providing the metallization structure on the ignition-deposited silicide layer from the ignition-deposited metal layer.

12. The method of claim 10, wherein providing the metallization structure on the ignition-deposited silicide layer comprises:
removing the ignition-deposited metal layer; and
providing the metallization structure on the ignition-deposited silicide layer.

13. The method of claim 9, wherein the ignition-deposited silicide layer comprises one of a nickel-silicide (NiSi) layer or titanium silicide (Ti₅Si₃).

14. A semiconductor device package, comprising:
a submount;
a semiconductor structure comprising a metastable-reactive-layer-deposited silicide; and
a metallization layer on the metastable-reactive-layer-deposited silicide, the metallization layer between the submount and the semiconductor structure.

15. The semiconductor device package of claim 14, further comprising nano-thermite residue on the semiconductor structure.

16. The semiconductor device package of claim 14, wherein the metastable-reactive-layer-deposited silicide and the metallization layer are formed based on an isolated exothermic reaction between the submount and the semiconductor structure, and wherein the isolated exothermic reaction is catalyzed by energy applied to a nano-thermite structure between the submount and the semiconductor structure, the energy being one of an electrical spark, a laser pulse, or an applied voltage.

17. The semiconductor device package of claim 16, wherein the nano-thermite structure comprises one or more metastable nano-thermites, the one or more metastable nano-thermites comprising one of aluminum-copper oxide (Al/CuO_{X}), aluminum-platinum (Al/Pt), palladium-aluminum (Pd/Al), nickel-aluminum (Ni/Al), zirconium-aluminum-cupronickel (Zr/Al/CuNi), silylrhodium (Rh/Si), a niobium-silicide (Nb/Si), a zirconium-silicide (Zr/Si), or a titanium-silicide (Ti/Si).

18. The semiconductor device package of claim 17, further comprising a die-attach material coupling the metallization layer to the submount, wherein the isolated exothermic reaction fuses the die-attach material to the metallization layer.

19. The semiconductor device package of claim 14, wherein the metallization layer is a backside metallization structure for the semiconductor device package, the backside metallization structure being a drain electrode for the semiconductor structure.

20. The semiconductor device package of claim 14, wherein the semiconductor structure comprises a wide bandgap semiconductor.
